(19) United States
(12) Patent Application Publication
(10) Pub. No.: US 2010/0275440 A1
(43) Pub. Date: Nov. 4, 2010

(54) HIGHLY CONDUCTIVE THERMAL INTERFACE AND NO PUMP-OUT THERMAL INTERFACE GREASES AND METHOD THEREFORE

(76) Inventors: SARA NAOMI PAISNER, Chapel Hill, NC (US); TONG WANG, Cary, NC (US)

Correspondence Address: LORD CORPORATION;PATENT & LEGAL SERVICES, 111 LORD DRIVE, P.O. Box 8012, CARY, NC, 27512-8012, US

(21) Appl. No.: 12/771,052

(22) Filed: Apr. 30, 2010

Related U.S. Application Data
(60) Provisional application No. 61/174,510, filed on May 1, 2009.

(51) Int. Cl. H05K 3/00; C09K 5/08

(52) U.S. Cl. 29/829; 252/68

(57) ABSTRACT

A high performance thermal conductive composition derived from an unsaturated diorganopolysiloxane and a saturated diorganopolysiloxane, a thermally conductive filler, and a silicone crosslinking agent without any cure step. The compositions unexpectedly have high thermal conductivity W-mK values, no observed pump-out, and good processing properties.

### CROSS REFERENCE

This patent application claims the benefit and priority of U.S. provisional application 61/174,510, filed May 1, 2009 for HIGHLY CONDUCTIVE NO CURE THERMAL INTERFACE GELS AND NO PUMP-OUT THERMAL INTERFACE GREASES AND METHOD FOR MANUFACTURING HIGHLY CONDUCTIVE NO CURE THERMAL INTERFACE GELS AND NO PUMP-OUT THERMAL INTERFACE GREASES, which is hereby fully incorporated by reference.

### FIELD OF THE INVENTION

The present invention relates to semiconductor processing, and particularly to materials and methods for packaging a semiconductor chip with a thermal interface material, and more particularly to unique processing of thermal interface materials that provide dramatic and unexpected increases in thermal conductivity, and unexpected low thermal resistance values.

### BACKGROUND OF THE INVENTION

Most electronic components, particularly solid state devices such as diodes, transistors and integrated circuitry, produce significant quantities of heat. To maintain their reliable operation it is necessary to remove heat from the operating components. Numerous means of promoting heat dissipation from operating electronic components have been proposed in the art. The principal mode of heat transfer in many designs is conduction of generated heat to a heat sink, such as the device package and/or circuit board, which is itself cooled by convection and radiation. The effectiveness of such design depends critically on the efficiency of heat transfer between the device and the heat sink.

One of the most common means for thermally coupling heat generating chips and associated heat sinks is by application of a thermally conductive grease or gel between the chip and the heat sink. Heat generated from the chip is efficiently conducted from the chip by the grease or gel to, for example, a module cap, where the heat is thereafter dissipated by radiation and convection into the ambient surroundings.

Thermally conductive greases for heat transfer in electronic devices are well known in the art. Typically, they comprise a liquid carrier and a thermally conductive filler in combination with other ingredients which function to thicken the grease and remove moisture from the grease. Functionally thermal greases should exhibit high thermal conductivity, low thermal resistivity, high thermal stability, and low surface tension to allow them to conform to the surface roughness and to wet heat transfer surfaces for maximizing the area of thermal contact. Further, the chemical makeup of thermal greases should be such that they are non-corrosive, electrically non-conductive and phase stable, i.e., non-bleeding and resistant to shear induced flocculation. Unfortunately, greases typically pump-out and separate during use. Pump-out leads to increased bulk thermal resistance and increased interfacial resistance. For high-end applications, such a change in both the bulk and interfacial resistance is unacceptable due to the resulting dramatic production in performance. Greases also have a tendency to dry out when used on a copper surface that endures extended periods of high temperatures.

### SUMMARY OF THE INVENTION

The present invention relates to a thermal conductive gelled composition that is a gelled grease. The silicone thermal conductive gelled grease compositions of the present invention have properties that exceed traditional thermal greases while not pumping-out. While optimal preparation methods for each application are dependent upon individual package types and set-ups, even with sub-optimal preparation that resulted in lower thermal transfer values, no pump-out was observed. The thermally conductive gelled greases of the present invention typically obtain at least thermal conductivity values of 4 W/mK.

For the purposes of this invention, the term “no cure gel” or “gelation without cure” mean compositions that are gelled without a separate cure step. That is, the compositions exhibit gel properties during use without a separate cure step regardless of what conditions they encounter in the chip package. In contrast, prior art gel compositions are typically cured at temperatures of 150° C. and higher which the present invention avoids. The extent of gel formation can readily be monitored with an oscillation test. The relative magnitudes of storage modulus (G′) and loss modulus (G″) are good indicators of the rheological state of the material. When G″ is greater in magnitude, the material behaves more as a liquid. Conversely, if G′ predominates, the material has more solid characteristics. During a thermosetting process, G″ will initially predominate in the uncured resin. As the curing process proceeds, G′ will increase at a faster rate than G″ as structure is formed. At some point, a “crossover” will occur, after which G′ is predominant. This crossover point is often referred to as the “gel point”, and empirically represents the “halfway” point between liquid and solid. Suitable gellation without cure ranges of the present invention extend from the gel point to the inflection point of the G′ curve where it levels out. In other words, from the empirical half-way gel point to about 80%, desirably about 70%, and preferably to about 65% of a completely solid state.

In an aspect of the present invention, a thermal interface composition (i.e. gelled grease) is provided comprising saturated and unsaturated silicone polymers, a silicone crosslinking agent, and a thermally conductive filler. The composition is gelled in-situ via the temperature generated by the electronics package itself thus removing the need for a separate cure step in the manufacture of a the electronics package.

In an embodiment of the present invention, the thermally conductive composition is generally applied at room temperature (ideally 20-25° C.), then applied to a substrate, and then allowed to gel slowly in-situ. In a preferred embodiment of the present invention, the temperature is maintained below 100° C. during the gelling step. In a more preferred embodiment of the present invention, the temperature is maintained below 85° C., and most preferably below 50° C. during the gelling step.

In another aspect of the invention, a method for producing a thermally conductive gelled grease comprises the steps of mixing a thermally conductive composition comprising a silicone, a thermally conductive filler, and a silicone crosslinking agent; allowing the mixture to form a gel without any cure step at a temperature below 100° C. and producing a thermally conductive grease.

### BRIEF DESCRIPTION OF THE DRAWINGS

FIG. 1 is a graph showing data with regard to reliability testing of a no cure formulation of the present invention;

FIG. 2 is a graph showing data with regard to reliability testing post package goes through a burn-in test of the thermally conductive composition of the present invention;

FIG. 3 is a photo of a Control and a thermal conductive gelled grease formulation of the present invention showing no pump-out; and

FIG. 4 is a graphic summary of Tables 6-8.

### DETAILED DESCRIPTION OF THE INVENTION

One component of the thermally conductive gelled grease of the present invention is a silicone polymer, that is a diorganopolysiloxane that contains at least one unsaturated group in any of the organo groups of the polymer and at least two total unsaturated groups in the entire polymer. A highly preferred unsaturated group (a double bond) is an alkenyl group containing from 2 to about 10 carbon atoms, a cycloalkenyl group, or an alkene substituent located on an aromatic compound such as phenyl. Alkenyl groups that can be bonded to a silicon atom include vinyl groups, allylic groups, butenyl groups, hexenyl groups, and the like. An example of a cylcoalkenyl compound is cyclohexane, and an example of an alkene substituted aromatic compound is styrene. The number of such unsaturated groups within the diorganopolysiloxane is at least 2 to about 3 or about 4 with from about 2.0 to about 2.5 being preferred per molecule, i.e. polymer chain. Examples of unsaturated orgnanopolysiloxanes that can be utilized are set forth in U.S. Pat. Nos. 3,220,972; and 3,410,886, hereby fully incorporated by reference. Specific examples of ethylenically-unsaturated organopolysiloxanes that are preferred are those containing higher alkenyl groups such as set forth in U.S. Pat. Nos. 4,609,574 and 6,770,326. Examples of preferred alkenyl-terminated diorganopolysiloxanes of the present invention include vinyl-methylpolysiloxane, vinylethylpolysiloxane, vinylpropylpolysiloxane, and vinylbutylpolysiloxane. Specific preferred unsaturated terminated diorganopolysiloxanes can be derived from vinyltrimethoxysilane, vinyltriethoxysilane, vinyltri-n-propoxysilane, vinyltri-iso-propoxysilane, vinyltri-n-butoxysilane, vinyltri-sec-butoxysilane, vinyltri-tert-butoxysilane, vinyltriphenoxysilane in a manner known to those skilled in the art and to the literature. The amount of the unsaturated diorganopolysiloxanes is from about 0.3 to about 0.6 and preferably from about 0.3 to about 0.45 mole percent based upon the total amount of the unsaturated and saturated diorganopolysiloxane polymers in the composition.

Another component of the thermally conductive gelled grease of the present invention is the utilization of a saturated diorganopolysiloxane wherein the substituent that is bonded to the silicon atom is a substituted or unsubstituted monovalent hydrocarbon group, e.g., alkyl groups having from 1 to 10 carbon atoms such as methyl groups, ethyl groups and propyl groups, etc.; aryl and alkyl substituted aryl groups such as phenyl groups and tolyl groups, etc.; and halogenated alkyl groups such as 3,3,3-trifluoropropyl groups, etc. Examples of other such monovalent hydrocarbon (saturated) containing polysiloxanes are set forth in U.S. Pat. Nos. 3,220,972; 3,410,886; and 6,770,326, hereby fully incorporated by reference. Preferred saturated diorganopolysiloxanes include dimethylpolysiloxane, diethylpolysiloxane, dipropylpolysiloxane, or methyl-ethylpolysiloxane, and combinations thereof. The amount of such saturated terminated diorganopolysiloxanes is generally from about 0.4 to about 0.7 mole percent and desirably from about 0.55 to about 0.7 mole percent based upon the total mole percent of all of said unsaturated terminated diorganopolysiloxanes and said saturated terminated diorganopolysiloxane polymers or chains.

The thermally conductive gelled grease of the present invention is produced by reacting a stoichiometric excess of the unsaturated and saturated terminated diorganopolysiloxanes with a multi-functional hydride-substituted organopolysiloxane crosslinking agent. The crosslinker can be a relatively low-molecular-weight H-functional oligosiloxane having from about 1 to about 5 repeat units, such as tetramethyldisiloxane, or a polymeric polydialkylsiloxane having SiH groups positioned along the chain or terminally having generally at least 6 to about 50 repeat units and wherein said alkyl group has from 1 to 10 carbon atoms, or a silicone resin having SiH groups. The structure of the molecules forming the crosslinker may vary. In particular, the structure of a higher-molecular-weight, i.e. oligomeric or polymeric, SiH-containing siloxane may be linear, cyclic, branched or else resin-like or network-like. Particular preference is given to the use of low-molecular-weight SiH-functional compounds, such as tetrakis(dimethylsiloxy)silane and tetramethylcyclotetrasiloxane, and also high-molecular-weight SiH-containing siloxanes, such as poly(hydromethyl)siloxane and poly(dimethylhydromethyl)siloxane, or analogous SiH-containing compounds in which some of the methyl groups have been replaced by 3,3,3-trifluoropropyl or phenyl groups.

In another preferred embodiment of the present invention, the crosslinker comprises an electro-negative group terminated siloxane oligomer. The electro-negative group terminated siloxane oligomers contain an electro-negative substituent in the terminating portion of the oligomeric compound include dimethylacetoxy-terminated polydimethylsiloxanes (PDMS), methyldiacetoxy-terminated PDMS, dimethylethoxy-terminated PDMS, aminopropyldimethyl-terminated PDMS, carbinol-terminated PDMS, monocarbinol-terminated PDMS, dimethylchloro-terminated PDMS, dimethylamino-terminated PDMS, dimethylethoxy-terminated PDMS, dimethylmethoxy PDMS, methacryloxypropyl-terminated PDMS, monomethylacryloxypropyl-terminated PDMS, carboxypropyldimethyl-terminated PDMS, chloromethyldimethyl-terminated PDMS, carboxypropyldimethyl-terminated PDMS and silanol-terminated polymethyl-3,3,3-trifluoropropylsiloxanes with monocarbinol-terminated PDMS being preferred. Electronegative terminated siloxane oligomers are available from Gelest Inc., under the MCR C-22 designation.

With respect to the crosslinker, either the hydride-terminated organopolysiloxane crosslinker or the electro-negative group terminated siloxane oligomer crosslinker can be utilized, or both, in an amount that provides from between 0.2 to about 5.0 moles of said crosslinker per mole of said unsaturated diorganopolysiloxane. The viscosity of the hydride-terminated organopolysiloxane and the electro-negative group terminated siloxane oligomer crosslinking agent can range from about 50 to about 20,000 and desirably from about 1,000 to about 10,000 cP at 25° C. The viscosity is determined by utilizing a Brookfield LVF viscosometer.

A catalyst is utilized to achieve partial crosslinking of the thermally conductive compositions. Such catalysts are hydrosilylation catalysts and contain at least one of the following elements: Pt, Rh, Ru, Pd, Ni, e.g. Raney Nickel, and their combinations. The catalyst is optionally coupled to an inert or active support. Examples of preferred catalysts which can be used include platinum type catalysts such as chloroplatinic acid, alcohol solutions of chloroplatinic acid, complexes of platinum and olefins, complexes of platinum and 1,3-divinyl-1,1,3,3-tetramethyldisiloxane and powders on which platinum is supported, etc. The platinum catalysts are fully described in the literature. Mention may in particular be made of the complexes of platinum and of an organic product described in U.S. Pat. Nos. 3,159,601, 3,159,602 and 3,220,972 and European Patents EP-A-057,459, EP-188,978 and EP-A-190,530 and the complexes of platinum and of vinylated organopolysiloxane described in U.S. Pat. Nos. 3,419,593, 3,715,334, 3,377,432, 3,814,730, and 3,775,452, to Karstedt. In particular, platinum type catalysts are especially desirable. An exemplary commercially available platinum catalyst is SIP 6830, available from Gelest, Inc. In the use of a platinum type catalyst the amount of platinum metal of this catalyst that is contained is in the range of from 0.01 to 1,000 ppm (in weight units), with an amount of platinum metal in the range of 0.1 to 500 ppm being preferred, alternatively, in terms of volume percent to total components, catalyst amount can range from 0.0001 to 0.1 volume % of the thermally conductive composition.

An important embodiment of the present invention is that the thermally conductive gelled grease comprises a filler, preferably a thermally conductive filler. The thermally conductive filler component of the compositions of the present invention can be selected from those thermally conductive fillers that have been used in the art to enhance thermal conductivity of commercially available, silicone fluid-based thermal greases. Thus the thermal filler component can be selected from a wide variety of thermally conductive particulate, preferably microparticulate, compositions including aluminum, silver, alumina, silica (including silica fibers), aluminum nitride, silicon carbide, boron nitride, zinc oxide, magnesium oxide, beryllium oxide, titanium dioxide, zirconium silicate, clays, talcs, zeolites and other minerals. Additionally, metallic fillers are available for use in the compositions of the present invention, such as silver, aluminum, gold, nickel, copper and the like. Preferred thermally conductive fillers include silver, aluminum, and zinc oxide, and any combination thereof.

Typically the thermally conductive filler is microparticulate powder having an average particle size ranging from about 0.1 to about 40 microns, and preferably from about 0.3 to about 20 microns. The amount of the one or more thermally conductive fillers is by far the largest amount of a component in the thermally conductive composition. Generally, from about 3 to about 10, desirably from about 4 to about 9, and preferably from about 5 to about 8 parts by weight of the one or more thermally conductive fillers is utilized for every 1.0 total part by weight of the various one or more crosslinkers, the one or more unsaturated diorganicpolysiloxanes, and the one or more saturated diorganicpolysiloxanes.

The general processing aspects of the present invention involve mixing the one or more unsaturated diorganopolysiloxane polymers, the one or more saturated diorganopolysiloxane polymers, and the one or more crosslinkers together, generally in any order, along with the one or more thermally conductive fillers and forming a mixture. Contemperaneously therewith or subsequently, the catalyst is added. Upon addition and mixing of the catalyst, crosslinking will occur.

An important aspect of the present invention is the formation of a thermally conductive gelled grease, without any separate curing step (i.e. free of any curing step) such as from about room temperature, for example 15° C. or about 20° C. to about 100° C., desirably from about room temperature to about 85° C., or to about 50° C., and preferably from about room temperature to about 30° C. Such low temperatures are important in that they have unexpectedly have been found to yield improved properties such as high thermal conductivity, high stability, low surface tension, low thermal resistivity values, and low modulus values at the G′ G″ crossover point. The thermally conductive compositions of the present invention can be applied to articles, components, substrates, etc., in any suitable manner such as by coating, brushing, spraying, casting, encapsulating, etc, to act as a heat sink. Thermal conductive values of the compositions of the present invention generally range from about 2 or about 3 to about 10, desirably from about 4 to about 9, and preferably from about 5 to about 8 W/mK. Also low thermal resistive values of about 16 or less, desirably about 10 or less and preferably about 6 or less mm²K/W are obtained. The low modulus crossover point values (i.e. gel point) are 8 or less, desirably about 6 or less and preferably about 3 or less KPa.

Another important aspect of the present invention is that the thermally conductive gelled grease have good wettable properties. These properties are in part derived from the utilization of various above-noted polysiloxanes, and also with regard to various wetting agents that can be added to the mixture in small amounts. Examples of suitable wetting agents include octamethycyclotetrasiloxane, hexamethycyclotetrasiloxane, heptamethycyclotetrasiloxane, pentamethycyclotetrasiloxane, nonamethycyclotetrasiloxane, and decamethycyclotetrasiloxane, generally in amounts of from about 0.1 to about 10 weight percent based upon the total weight of the unsaturated and saturated diorganopolysiloxanes and crosslinking agents.

The present invention will be better understood by reference to the following examples which serve to illustrate, but not to limit the invention.

### EXAMPLES

The components of Formulation A and B are listed in Table 1 and form a gelled grease. Each formulation is separately prepared as follows. To a 100 g cup, the alkyl siloxanes, silicones, vinyl group-terminated organomodified siloxanes, catalyst, and electronegative group terminated PDMS were added and mixed under high shear mixing for 30 seconds at 2000 rpm. The aluminum powder and zinc oxide powder were added and then mixed under high shear mixing for 30 seconds at 2000 rpm. The formulation was then allowed to cool to room temperature. Small amounts of the crosslinker were added and mixed under high shear mixing for 10 seconds at 2000 rpm and then cooled to room temperature. The formulation was checked to confirm that it was well mixed. If not, the final mixing step was repeated, and cooled to room temperature until the formulation was fully mixed. No cure step was utilized for Formulations A and B.

In an exact same manner the same components and amounts of Formulation A set forth in Table 1 was cured for 30 minutes of 150° C. to provide a Control. The Control and gelled grease A of the present invention were tested and provided the following comparative data set forth in Table 2 utilizing the Nanoflash sandwich method.

TABLE 1

| | A | B |
|---|---|---|
| chemical name | wt % | wt % |
| POLYMER, V200/DV-200 a vinyl terminated | 8.7 | 5.9 |
| diorganopolysiloxane | | |
| THERMOSET CATALYST PREBLEND FOR MG200A | 1.7 | 1.7 |
| a platinum-divinyltetramethyldisiloxane complex 3- | | |
| 3.5 wt % Pt in vinyl-terminated PDMS | | |
| GELEST MCR-C22 Monocarboniol terminated PDMS | 0.69 | 0.88 |
| DMS-E12 a saturated dimethyl polysiloxane | 0.50 | 0 |
| S-292 ATOMIZED ALUMINUM an aluminum particle | 52 | 51 |
| filler | | |
| VMS T-11 retarder vinylmethylsiloxane homopolymer | 1.2 | 0.84 |
| ZINC OXIDE USP-2 zinc oxide | 35 | 0 |
| WITCO V-XL FLUID a vinyl terminated polysiloxane | 0.58 | 0.42 |
| crosslinker | | |
| AKROCHEM RGT-Z ZINC OXIDE 210 NM zinc oxide | 0 | 40 |

TABLE 2
Comparative Data

| | Control | Formula A |
|---|---|---|
| Typical Properties (Uncured/Ungelled): | | |
| Viscosity @ 25° C. (cps) (5/sec) | 105,900 | 105,900 |
| Typical Properties (Cured/Gelled): | | |
| Coefficient of Linear Thermal Expansion | 178 | 178 |
| (ppm/° C.) | | |
| Thermal Conductivity (W/mK) | 3.8 | 6-8 W/mK |
| Glass Transition Temperature (Tg, ° C.) | −119 | −119 |
| Modulus at G′G″ crossover point (KPa) | 9.7 | 0.9-3 |
| Final Modulus (KPa) | 20 | ~6 |

As apparent from Table 2, the process of the present invention yielded dramatic and unexpected improvement with regard to thermal conductivity, i.e. a value of from 3.8 to 6 to 8, an increase of from about 58% to about 110%! With respect to the G′ G″ crossover point modulus, unexpected improvements were obtained of 0.9-3 KPa versus 9.7 for the control. A reduction at least 300%. The thermally conductive grease also had low surface tension, was phase stable, and had no pump-out.

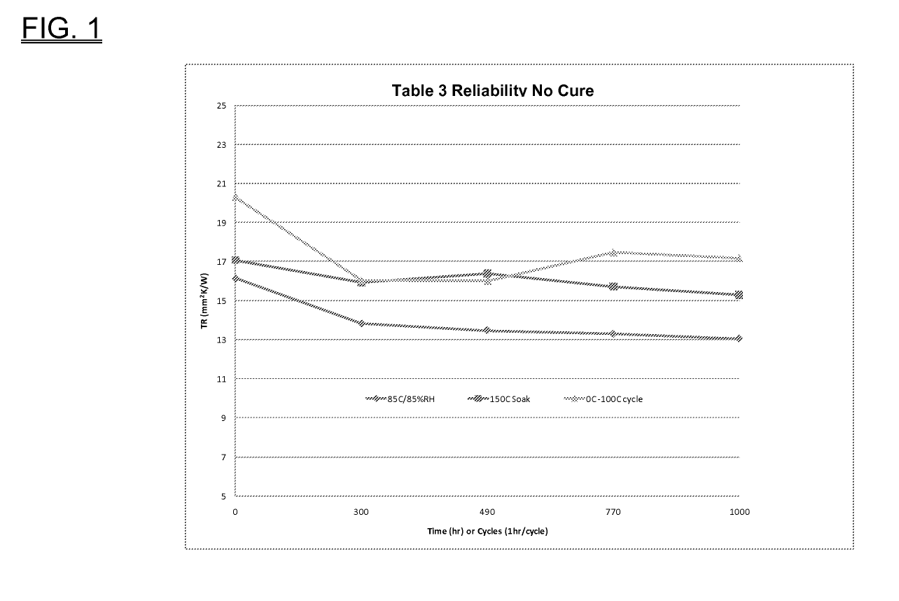

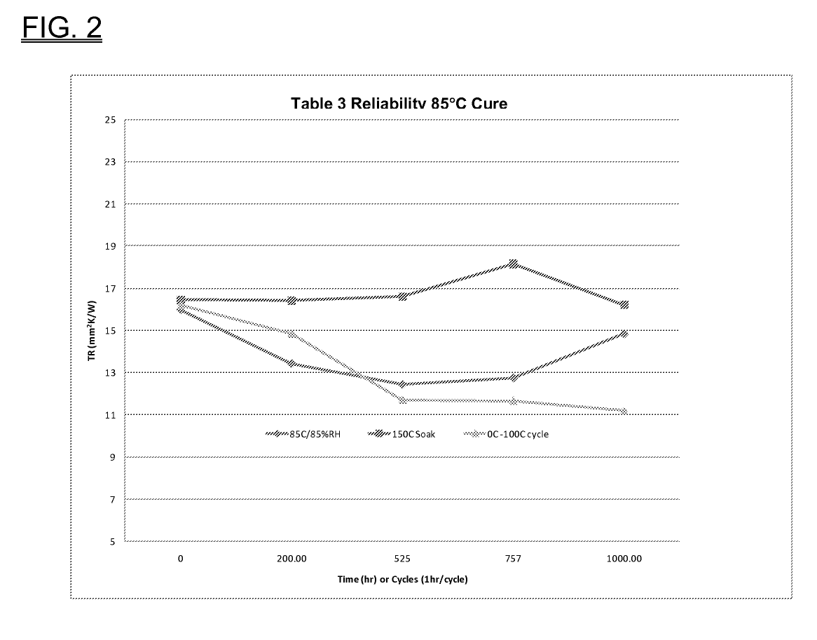

The above A formulation was tested with regard to a 85° C./85% relative humidity test, a 150° C. high temperatures soak test and a 0° C. to 100° C. thermal cycling test that are known to the art. The results are set forth in Tables 3, 4, and 5. Moreover, FIGS. 1 and 2 correspond to the data set forth in Tables 3, 4, and 5, respectively.

Tested to mimic an as-dispensed (into an electronics package)
TABLE 3A

| | Condition | | | | | | |
|---|---|---|---|---|---|---|---|
| | 85° C./85% RH | | | | | | |
| Time (hr) | | 1 | 2 | 3 | 4 | Average | Std Dev. |
| 0 | BLT (mm) | 0.06 | 0.048 | 0.047 | 0.049 | 0.051 | 0.006055 |
| | eff TC | 3.31 | 3.07 | 3.01 | 3.23 | 3.15325 | 0.137398 |
| | (W/Mk) | | | | | | |
| | TR (mm²- | 18.1 | 15.7 | 15.6 | 15.2 | 16.14591 | 1.352551 |
| | K/W) | | | | | | |
| 300 | BLT (mm) | 0.057 | 0.042 | 0.043 | 0.043 | 0.04625 | 0.007182 |
| | eff TC | 3.63 | 3.18 | 3.24 | 3.29 | 3.3325 | 0.201128 |
| | (W/mK) | | | | | | |
| | TR (mm²- | 15.7 | 13.2 | 13.3 | 13.1 | 13.82344 | 1.267649 |
| | K/W) | | | | | | |
| 490 | BLT (mm) | 0.061 | 0.047 | 0.046 | 0.047 | 0.05025 | 0.007182 |
| | eff TC | 4.01 | 3.59 | 3.54 | 3.75 | 3.721 | 0.211814 |
| | (W/mK) | | | | | | |
| | TR (mm²- | 15.2 | 13.1 | 13.0 | 12.5 | 13.46347 | 1.196321 |
| | K/W) | | | | | | |
| 770 | BLT (mm) | 0.056 | 0.043 | 0.047 | 0.044 | 0.0475 | 0.005916 |
| | eff TC | 3.78 | 3.36 | 3.62 | 3.50 | 3.566 | 0.176771 |
| | (W/mK) | | | | | | |
| | TR (mm²- | 14.8 | 12.8 | 13.0 | 12.6 | 13.28858 | 1.041754 |
| | K/W) | | | | | | |
| 1000 | BLT (mm) | 0.056 | 0.043 | 0.047 | 0.044 | 0.0475 | 0.005916 |
| | eff TC | 3.86 | 3.44 | 3.73 | 3.50 | 3.6335 | 0.196826 |
| | (W/mK) | | | | | | |
| | TR (mm²- | 14.5 | 12.5 | 12.6 | 12.6 | 13.04101 | 0.968965 |
| | K/W) | | | | | | |

Condition
80°5 C/85% RH

| | | Avg TC |
|---|---|---|
| Time (hr) | Avg TR (mm2-K/W) | (W/mK) |
| 0 | 16 | 3.2 |
| 300 | 14 | 3.3 |
| 490 | 13 | 3.7 |
| 770 | 13 | 3.6 |
| 1000 | 13 | 3.6 |

TABLE 3B

| | Condition | | | | | | |
|---|---|---|---|---|---|---|---|
| | 150° C. High Temperature Soak | | | | | | |
| Time (hr) | | 1 | 2 | 3 | 4 | Average | Std Dev. |
| 0 | BLT (mm) | 0.048 | 0.05 | 0.054 | 0.048 | 0.05 | 0.002828 |
| | eff TC | 2.81 | 3.09 | 2.72 | 3.17 | 2.94625 | 0.21791 |
| | (W/mK) | | | | | | |
| | TR (mm²- | 17.1 | 16.2 | 19.9 | 15.1 | 17.07251 | 2.024417 |
| | K/W) | | | | | | |
| 310 | BLT (mm) | 0.046 | 0.048 | 0.052 | 0.047 | 0.04825 | 0.00263 |
| | eff TC | 2.96 | 3.18 | 2.86 | 3.16 | 3.0405 | 0.153644 |
| | (W/mK) | | | | | | |
| | TR (mm²- | 15.5 | 15.1 | 18.2 | 14.9 | 15.91856 | 1.517347 |
| | K/W) | | | | | | |
| 500 | BLT (mm) | 0.044 | 0.042 | 0.052 | 0.046 | 0.046 | 0.00432 |
| | eff TC | 2.91 | 3.41 | 2.26 | 3.06 | 2.90825 | 0.483399 |
| | (W/mK) | | | | | | |
| | TR (mm²- | 15.1 | 12.3 | 23.0 | 15.1 | 16.38424 | 4.632839 |
| | K/W) | | | | | | |
| 780 | BLT (mm) | 0.043 | 0.04 | 0.049 | 0.042 | 0.0435 | 0.003873 |
| | eff TC | 2.78 | 2.70 | 2.76 | 2.84 | 2.7675 | 0.056595 |
| | (W/mK) | | | | | | |
| | TR (mm²- | 15.5 | 14.8 | 17.8 | 14.8 | 15.72008 | 1.398574 |
| | K/W) | | | | | | |
| 1000 | BLT (mm) | 0.043 | 0.042 | 0.052 | 0.046 | 0.04575 | 0.0045 |
| | eff TC | 2.85 | 2.91 | 2.97 | 3.26 | 2.99575 | 0.179312 |
| | (W/mK) | | | | | | |
| | TR (mm²- | 15.1 | 14.4 | 17.5 | 14.1 | 15.29317 | 1.536622 |
| | K/W) | | | | | | |

Condition
150° C. High Temp Soak

| | Avg TR (mm2- | |
|---|---|---|
| Time (hr) | K/W) | Avg TC (W/mK) |
| 0 | 17 | 2.9 |
| 310 | 16 | 3.0 |
| 500 | 16 | 2.9 |
| 780 | 16 | 2.8 |
| 1000 | 15 | 3.0 |

TABLE 3C

| | Condition | | | | | | |
|---|---|---|---|---|---|---|---|
| | 0° C.-100° C. cycle | | | | | | |
| Time (hr) | | 1 | 2 | 3 | 4 | Average | Std Dev. |
| 0 | BLT (mm) | 0.053 | 0.05 | 0.063 | 0.062 | 0.057 | 0.006481 |
| | eff TC | 2.77 | 2.83 | 2.82 | 2.82 | 2.81 | 0.028308 |
| | (W/mK) | | | | | | |
| | TR (mm²- | 19.1 | 17.6 | 22.4 | 22.0 | 20.28304 | 2.270169 |
| | K/W) | | | | | | |
| 267 | BLT (mm) | 0.048 | 0.044 | 0.059 | 0.053 | 0.051 | 0.006481 |
| | eff TC | 3.16 | 3.31 | 3.02 | 3.29 | 3.195 | 0.136794 |
| | (W/mK) | | | | | | |
| | TR (mm²- | 15.2 | 13.3 | 19.6 | 16.1 | 16.03468 | 2.632781 |
| | K/W) | | | | | | |
| 503 | BLT (mm) | 0.048 | 0.044 | 0.059 | 0.052 | 0.05075 | 0.006397 |
| | eff TC | 3.17 | 3.33 | 2.94 | 3.34 | 3.1955 | 0.186548 |
| | (W/mK) | | | | | | |
| | TR (mm²- | 15.2 | 13.2 | 20.0 | 15.6 | 15.99489 | 2.893854 |
| | K/W) | | | | | | |
| 836 | BLT (mm) | 0.052 | 0.044 | 0.059 | 0.054 | 0.05225 | 0.006238 |
| | eff TC | 3.26 | 3.16 | 2.52 | 3.28 | 3.05225 | 0.361591 |
| | (W/mK) | | | | | | |
| | TR (mm²- | 16.0 | 13.9 | 23.4 | 16.5 | 17.4551 | 4.142343 |
| | K/W) | | | | | | |
| 1000 | BLT (mm) | 0.052 | 0.044 | 0.059 | 0.054 | 0.05225 | 0.006238 |
| | eff TC | 3.32 | 3.16 | 2.56 | 3.36 | 3.10175 | 0.369633 |
| | (W/mK) | | | | | | |
| | TR (mm²- | 15.7 | 13.9 | 23.0 | 16.1 | 17.16476 | 4.011898 |
| | K/W) | | | | | | |

Condition
0° C.-100° C. cycle

| | | Avg TC |
|---|---|---|
| Time (hr) | Avg TR (mm2-K/W) | (W/mK) |
| 0 | 20 | 2.8 |
| 267 | 16 | 3.2 |
| 503 | 16 | 3.2 |
| 836 | 17 | 3.1 |
| 1000 | 17 | 3.1 |

Tested to represent moderate heat exposure in package
TABLE 4A

| | Condition | | | | | |
|---|---|---|---|---|---|---|
| | 85° C./85% RH | | | | | |
| Time (hr) | | 1 | 2 | 3 | 4 | Avg |
| 0 | BLT (mm) | 0.066 | 0.056 | 0.065 | 0.056 | 0.06075 |
| | eff TC | 2.27 | 3.42 | 3.23 | 2.95 | 2.96675 |
| | (W/mK) | | | | | |
| | TR (mm²- | 29.0 | 16.4 | 20.1 | 19.0 | 21.1381 |
| | K/W) | | | | | |
| 260 | BLT (mm) | 0.062 | 0.052 | 0.063 | 0.057 | 0.0585 |
| | eff TC | 2.60 | 4.20 | 4.08 | 3.84 | 3.6805 |
| | (W/mK) | | | | | |
| | TR (mm²- | 23.8 | 12.4 | 15.4 | 14.9 | 16.62276 |
| | K/W) | | | | | |
| 500 | BLT (mm) | 0.064 | 0.054 | 0.066 | 0.058 | 0.0605 |
| | eff TC | 2.60 | 4.66 | 4.59 | 4.10 | 3.98775 |
| | (W/mK) | | | | | |
| | TR (mm²- | 24.6 | 11.6 | 14.4 | 14.1 | 16.17571 |
| | K/W) | | | | | |
| 750 | BLT (mm) | 0.063 | 0.052 | 0.066 | 0.057 | 0.0595 |
| | eff TC | 2.53 | 4.71 | 3.20 | 4.23 | 3.668 |
| | (W/mK) | | | | | |
| | TR (mm²- | 24.9 | 11.0 | 20.7 | 13.5 | 17.51294 |
| | K/W) | | | | | |
| 1000 | BLT (mm) | 0.065 | 0.054 | 0.066 | 0.055 | 0.06 |
| | eff TC | 2.55 | 6.97 | 2.94 | 4.10 | 4.139 |
| | (W/mK) | | | | | |
| | TR (mm²- | 25.5 | 7.7 | 22.4 | 13.4 | 17.28426 |
| | K/W) | | | | | |

Condition
85° C./85% RH

| | Avg TR (mm2- | Avg TC |
|---|---|---|
| Time (hr) | K/W) | (W/mK) |
| 0 | 21 | 3.0 |
| 260 | 17 | 3.7 |
| 500 | 16 | 4.0 |
| 750 | 18 | 3.7 |
| 1000 | 17 | 4.1 |

TABLE 4B

| | Condition | | | | | |
|---|---|---|---|---|---|---|
| | 150° C. High Temperature Soak | | | | | |
| Time (hr) | | 1 | 2 | 3 | 4 | Avg |
| 0 | BLT (mm) | 0.049 | 0.072 | 0.065 | 0.064 | 0.0625 |
| | eff TC | 2.84 | 3.15 | 3.28 | 3.56 | 3.208 |
| | (W/mK) | | | | | |
| | TR (mm²- | 17.2 | 22.9 | 19.8 | 18.0 | 19.47531 |
| | K/W) | | | | | |
| 260 | BLT (mm) | 0.048 | 0.071 | 0.062 | 0.058 | 0.05975 |
| | eff TC | 2.94 | 3.16 | 3.27 | 3.25 | 3.15425 |
| | (W/mK) | | | | | |
| | TR (mm²- | 16.3 | 22.5 | 19.0 | 17.9 | 18.90561 |
| | K/W) | | | | | |
| 500 | BLT (mm) | 0.048 | 0.069 | 0.061 | 0.057 | 0.05875 |
| | eff TC | 2.99 | 3.12 | 3.22 | 3.23 | 3.13875 |
| | (W/mK) | | | | | |
| | TR (mm²- | 16.1 | 22.1 | 18.9 | 17.7 | 18.69797 |
| | K/W) | | | | | |
| 760 | BLT (mm) | 0.045 | 0.068 | 0.061 | 0.056 | 0.0575 |
| | eff TC | 2.88 | 3.13 | 3.35 | 3.25 | 3.1485 |
| | (W/mK) | | | | | |
| | TR (mm²- | 15.7 | 21.8 | 18.2 | 17.2 | 18.22103 |
| | K/W) | | | | | |
| 1000 | BLT (mm) | 0.047 | 0.068 | 0.06 | 0.058 | 0.05825 |
| | eff TC | 2.99 | 3.10 | 3.25 | 3.37 | 3.174 |
| | (W/mK) | | | | | |
| | TR (mm²- | 15.7 | 22.0 | 18.5 | 17.2 | 18.35252 |
| | K/W) | | | | | |

Condition
150° C. High Temp Soak

| Time (hr) | Avg TR (mm2-K/W) | Avg TC (W/mK) |
|---|---|---|
| 0 | 19 | 3.2 |
| 260 | 19 | 3.2 |
| 500 | 19 | 3.1 |
| 760 | 18 | 3.1 |
| 1000 | 18 | 3.2 |

TABLE 4C

| | Condition | | | | | |
|---|---|---|---|---|---|---|
| | 0° C.-100° C. cycle | | | | | |
| Time (hr) | | 1 | 2 | 3 | 4 | Avg |
| 0 | BLT (mm) | 0.086 | 0.09 | 0.081 | 0.053 | 0.0775 |
| | eff TC | 6.74 | 3.73 | 2.84 | 2.22 | 3.88025 |
| | (W/mK) | | | | | |
| | TR (mm²- | 12.8 | 24.1 | 28.5 | 23.9 | 22.33271 |
| | K/W) | | | | | |
| 256 | BLT (mm) | 0.077 | 0.08 | 0.07 | 0.044 | 0.06775 |
| | eff TC | 3.67 | 2.82 | 3.80 | 3.50 | 3.44675 |
| | (W/mK) | | | | | |
| | TR (mm²- | 21.0 | 28.4 | 18.4 | 12.6 | 20.09105 |
| | K/W) | | | | | |
| 487 | BLT (mm) | 0.077 | 0.081 | 0.068 | 0.045 | 0.06775 |
| | eff TC | 3.72 | 2.68 | 3.72 | 3.63 | 3.437 |
| | (W/mK) | | | | | |
| | TR (mm²- | 20.7 | 30.3 | 18.3 | 12.4 | 20.40896 |
| | K/W) | | | | | |
| 743 | BLT (mm) | 0.076 | 0.08 | 0.068 | 0.043 | 0.06675 |
| | eff TC | 3.47 | 2.70 | 3.49 | 3.60 | 3.31325 |
| | (W/mK) | | | | | |
| | TR (mm²- | 21.9 | 29.6 | 19.5 | 12.0 | 20.74777 |
| | K/W) | | | | | |
| 980 | BLT (mm) | 0.074 | 0.079 | 0.068 | 0.044 | 0.06625 |
| | eff TC | 3.37 | 2.67 | 3.76 | 3.66 | 3.3665 |
| | (W/mK) | | | | | |
| | TR (mm²- | 21.9 | 29.6 | 18.1 | 12.0 | 20.40564 |
| | K/W) | | | | | |

Condition
0° C.-100° C. cycle

| | Avg TR (mm2- | |
|---|---|---|
| Time (hr) | K/W) | Avg TC (W/mK) |
| 0 | 22 | 3.9 |
| 256 | 20 | 3.4 |
| 487 | 20 | 3.4 |
| 743 | 21 | 3.3 |
| 980 | 20 | 3.4 |

Tested to represent high power exposure package
TABLE 5A

| | Condition | | | | | |
|---|---|---|---|---|---|---|
| | 85° C./85% RH | | | | | |
| Time (hr) | | 1 | 2 | 3 | 4 | Avg |
| 0 | BLT (mm) | 0.045 | 0.04 | 0.042 | 0.03 | 0.03925 |
| | eff TC | 2.29 | 2.16 | 2.86 | 2.71 | 2.505 |
| | (W/mK) | | | | | |
| | TR (mm²- | 19.7 | 18.5 | 14.7 | 11.1 | 15.98652 |
| | K/W) | | | | | |
| 200 | BLT (mm) | 0.045 | 0.039 | 0.047 | 0.028 | 0.03975 |
| | eff TC | 2.66 | 2.49 | 3.99 | 3.00 | 3.0365 |
| | (W/mK) | | | | | |
| | TR (mm²- | 16.9 | 15.7 | 11.8 | 9.3 | 13.41687 |
| | K/W) | | | | | |
| 506 | BLT (mm) | 0.045 | 0.037 | 0.047 | 0.028 | 0.03925 |
| | eff TC | 2.96 | 2.53 | 3.95 | 3.49 | 3.23525 |
| | (W/mK) | | | | | |
| | TR (mm²- | 15.2 | 14.6 | 11.9 | 8.0 | 12.42494 |
| | K/W) | | | | | |
| 750 | BLT (mm) | 0.047 | 0.038 | 0.048 | 0.028 | 0.04025 |
| | eff TC | 3.24 | 2.18 | 4.62 | 3.24 | 3.3205 |
| | (W/mK) | | | | | |
| | TR (mm²- | 14.5 | 17.4 | 10.4 | 8.6 | 12.7399 |
| | K/W) | | | | | |
| 1050 | BLT (mm) | 0.048 | 0.035 | 0.05 | 0.029 | 0.0405 |
| | eff TC | 2.93 | 1.38 | 5.18 | 3.68 | 3.28925 |
| | (W/mK) | | | | | |
| | TR (mm²- | 16.4 | 25.3 | 9.7 | 7.9 | 14.82626 |
| | K/W) | | | | | |

| | Condition |
|---|---|
| | 85° C./85% RH |
| Time (hr) | Avg TR (mm2-K/W) |
| 0 | 16 |
| 200.00 | 13 |
| 506 | 12 |
| 750 | 13 |
| 1050.00 | 15 |

TABLE 5B

| | Condition | | | | | |
|---|---|---|---|---|---|---|
| | 150° C. High Temperature Soak | | | | | |
| Time (hr) | | 1 | 2 | 3 | 4 | Avg |
| 0 | BLT (mm) | 0.069 | 0.062 | 0.038 | 0.054 | 0.05575 |
| | eff TC | 3.73 | 3.80 | 2.96 | 2.98 | 3.36675 |
| | (W/mK) | | | | | |
| | TR (mm²- | 18.5 | 16.3 | 12.8 | 18.1 | 16.44474 |
| | K/W) | | | | | |
| 245 | BLT (mm) | 0.067 | 0.055 | 0.035 | 0.044 | 0.05025 |
| | eff TC | 3.48 | 3.41 | 2.75 | 2.51 | 3.03725 |
| | (W/mK) | | | | | |
| | TR (mm²- | 19.2 | 16.1 | 12.8 | 17.5 | 16.40931 |
| | K/W) | | | | | |
| 570 | BLT (mm) | 0.067 | 0.045 | 0.034 | 0.044 | 0.0475 |
| | eff TC | 3.40 | 2.83 | 2.65 | 2.45 | 2.83325 |
| | (W/mK) | | | | | |
| | TR (mm²- | 19.7 | 15.9 | 12.8 | 17.9 | 16.59303 |
| | K/W) | | | | | |
| 790 | BLT (mm) | 0.07 | 0.049 | 0.038 | 0.068 | 0.05625 |
| | eff TC | 3.75 | 3.02 | 2.96 | 2.73 | 3.11725 |
| | (W/mK) | | | | | |
| | TR (mm²- | 18.7 | 16.2 | 12.8 | 24.9 | 18.14452 |
| | K/W) | | | | | |
| 1050 | BLT (mm) | 0.064 | 0.049 | 0.036 | 0.051 | 0.05 |
| | eff TC | 3.42 | 3.09 | 2.83 | 2.91 | 3.06125 |
| | (W/mK) | | | | | |
| | TR (mm²- | 18.7 | 15.8 | 12.7 | 17.5 | 16.2115 |
| | K/W) | | | | | |

| | Condition |
|---|---|
| | 150° C. High Temp Soak |
| Time (hr) | Avg TR (mm2-K/W) |
| 0 | 16 |
| 245.00 | 16 |
| 570 | 17 |
| 790 | 18 |
| 1000.00 | 16 |

TABLE 5C

| | Condition | | | | | |
|---|---|---|---|---|---|---|
| | 0° C.-100° C. cycle | | | | | |
| Time (hr) | | 1 | 2 | 3 | 4 | Avg |
| 0 | BLT (mm) | 0.033 | 0.04 | 0.05 | 0.054 | 0.04425 |
| | eff TC | 2.31 | 2.75 | 2.85 | 2.93 | 2.71225 |
| | (W/mK) | | | | | |
| | TR (mm²- | 14.3 | 14.5 | 17.5 | 18.4 | 16.18802 |
| | K/W) | | | | | |
| 200 | BLT (mm) | 0.031 | 0.037 | 0.038 | 0.049 | 0.03875 |
| | eff TC | 2.63 | 2.87 | 2.48 | 2.52 | 2.6245 |
| | (W/mK) | | | | | |
| | TR (mm²- | 11.8 | 12.9 | 15.3 | 19.4 | 14.86097 |
| | K/W) | | | | | |
| 525 | BLT (mm) | 0.033 | 0.035 | 0.043 | 0.047 | 0.0395 |
| | eff TC | 3.06 | 3.38 | 3.20 | 3.84 | 3.37075 |
| | (W/mK) | | | | | |
| | TR (mm²- | 10.8 | 10.4 | 13.4 | 12.2 | 11.70133 |
| | K/W) | | | | | |
| 757 | BLT (mm) | 0.031 | 0.032 | 0.04 | 0.046 | 0.03725 |
| | eff TC | 2.83 | 3.06 | 3.02 | 3.84 | 3.18675 |
| | (W/mK) | | | | | |
| | TR (mm²- | 10.9 | 10.5 | 13.3 | 12.0 | 11.66226 |
| | K/W) | | | | | |
| 1000 | BLT (mm) | 0.033 | 0.03 | 0.04 | 0.048 | 0.03775 |
| | eff TC | 2.84 | 2.26 | 4.31 | 4.55 | 3.4895 |
| | (W/mK) | | | | | |
| | TR (mm²- | 11.6 | 13.3 | 9.3 | 10.5 | 11.18392 |
| | K/W) | | | | | |

| | Condition |
|---|---|
| | 0° C.-100° C. cycle |
| Time (hr) | Avg TR (mm2-K/W) |
| 0 | 16 |
| 200.00 | 15 |
| 525 | 12 |
| 757 | 12 |
| 1000.00 | 11 |

All three conditions showed excellent reliability as compared to standard cured greases (which will show pump out and separation long before reaching 1000 cycles.) By removing the need for a cure step, surprisingly, unexpected improved properties were obtained with regard to thermal conductivity as well as thermal resistivity of Formulation A. This new thermal gel can be used in a wider variety of applications, specifically ones that would normally not survive high temperatures due to the package complexity or detail.

The gelled grease composition of the present invention is an example of a material that can be used in all grease applications, but will not pump-out or separate as normally observed in standard or conventional greases. Additionally, higher thermal conducitivites are observed due to the extremely slow structuring step that allows for maximum wetting at the substrate interfaces. This is an important aspect as the interfacial wetting can have a large effect on observed thermal conductivity due to its contribution to the thermal resistance.

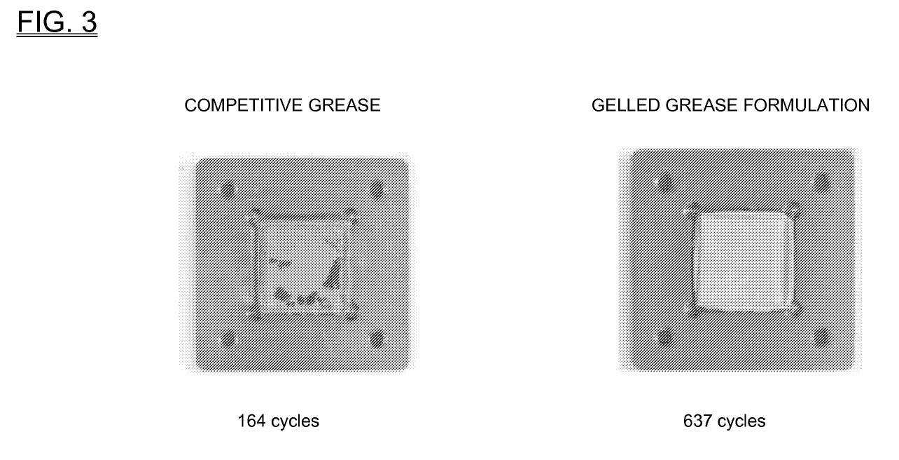

The gelled Formulation A grease was tested against the Control noted hereinabove with regard to a no pump-out grease liability testing thermal cycling time-lapse images and the results thereof are set forth in FIG. 3. As apparent from FIG. 3, the competitive grease showed separation of the components, i.e. the dark spots, whereas the gelled grease formulation of the present invention showed no pump-out at all after 637 cycles; i.e. a factor 3.8 times greater than the cycles of the competitive grease!

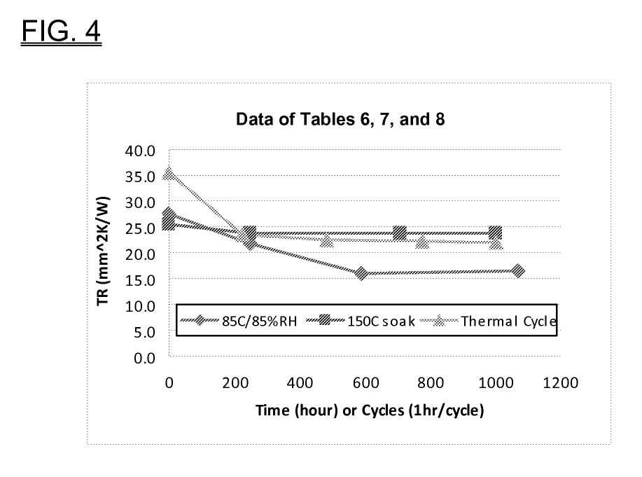

The B formulation of Table 1 was also tested with regard to 85° C./85% relative humidity test, a 150° C. high temperature soak test and a 0° C. to 100° C. thermal cycling test. The results are set forth in Tables 6, 7, and 8 and the data therefrom is set forth in FIG. 4.

as dispensed into package

| | | | | |
|---|---|---|---|---|
| 1 | 2 | 3 | 4 | avg |

TABLE 6A

| | | | | | | | | |
|---|---|---|---|---|---|---|---|---|
| 85° C./85% | t = 0 | 0 | BLT (mm) | 0.124 | 0.117 | 0.123 | 0.131 | |
| RH | | | Eff TC | 4.162 | 4.296 | 4.483 | 5.131 | 4.5 |
| | | | (W/m · K) | | | | | |
| | | | TR (mm2- | 29.8 | 27.2 | 27.4 | 25.5 | 27.5 |
| | | | K/W) | | | | | |
| | t = 250 hrs | 250 | BLT (mm) | 0.123 | 0.112 | 0.12 | 0.12 | |
| | | | Eff TC | 5.155 | 5.928 | 4.724 | 6.329 | 5.5 |
| | | | (W/m · K) | | | | | |
| | | | TR (mm2- | 23.9 | 18.9 | 25.4 | 19.0 | 21.8 |
| | | | K/W) | | | | | |
| | t = 590 hrs | 590 | BLT (mm) | 0.129 | 0.12 | 0.123 | 0.13 | |
| | | | Eff TC | 6.883 | 7.635 | 8.257 | 9.098 | 8.0 |
| | | | (W/m · K) | | | | | |
| | | | TR (mm2- | 18.7 | 15.7 | 14.9 | 14.3 | 15.9 |
| | | | K/W) | | | | | |
| | t = 1070 hrs | 1070 | BLT (mm) | 0.123 | 0.116 | 0.122 | 0.129 | |
| | | | Eff TC | 6.28 | 7.003 | 8.268 | 8.62 | 7.5 |
| | | | (W/m · K) | | | | | |
| | | | TR (mm2- | 19.6 | 16.6 | 14.8 | 15.0 | 16.5 |
| | | | K/W) | | | | | |

TABLE 6B

| | | | | | | | | |
|---|---|---|---|---|---|---|---|---|
| 150° C. | t = 0 | 0 | BLT (mm) | 0.116 | 0.106 | 0.106 | 0.119 | |
| soak | | | Eff TC | 4.261 | 3.49 | 5.436 | 4.778 | 4.5 |
| | | | (W/m · K) | | | | | |
| | | | TR (mm2- | 27.2 | 30.4 | 19.5 | 24.9 | 25.5 |
| | | | K/W) | | | | | |
| | t = 250 hrs | 250 | BLT (mm) | 0.121 | 0.107 | 0.109 | 0.114 | |
| | | | Eff TC | 4.684 | 4.117 | 5.774 | 4.721 | 4.8 |
| | | | (W/m · K) | | | | | |
| | | | TR (mm2- | 25.8 | 26.0 | 18.9 | 24.1 | 23.7 |
| | | | K/W) | | | | | |
| | t = 710 hrs | 710 | BLT (mm) | 0.116 | 0.106 | 0.104 | 0.114 | |
| | | | Eff TC | 4.683 | 4.095 | 5.273 | 4.714 | 4.7 |
| | | | (W/m · K) | | | | | |
| | | | TR (mm2- | 24.8 | 25.9 | 19.7 | 24.2 | 23.6 |
| | | | K/W) | | | | | |
| | t = 1000 hrs | 1000 | BLT (mm) | 0.109 | 0.091 | 0.091 | 0.105 | |
| | | | Eff TC | 4.399 | 3.547 | 4.517 | 4.246 | 4.2 |
| | | | (W/m · K) | | | | | |
| | | | TR (mm2- | 24.8 | 25.7 | 20.1 | 24.7 | 23.8 |
| | | | K/W) | | | | | |

TABLE 6C

| | | | | | | | | |
|---|---|---|---|---|---|---|---|---|
| Thermal | t = 0 | 0 | BLT (mm) | 0.16 | 0.141 | 0.13 | 0.147 | |
| Cycle | | | Eff TC | 4.439 | 4.055 | 3.255 | 4.716 | 4.1 |
| 0° C.-110° C. | | | (W/m · K) | | | | | |
| | | | TR (mm2- | 36.0 | 34.8 | 39.9 | 31.2 | 35.5 |
| | | | K/W) | | | | | |
| | t = 225 | 225 | BLT (mm) | 0.127 | 0.11 | 0.099 | 0.118 | |
| | cycles | | Eff TC | 5.375 | 4.666 | 3.847 | 5.533 | 4.9 |
| | | | (W/m · K) | | | | | |
| | | | TR (mm2- | 23.6 | 23.6 | 25.7 | 21.3 | 23.6 |
| | | | K/W) | | | | | |
| | t = 485 | 485 | BLT (mm) | 0.141 | 0.126 | 0.112 | 0.132 | |
| | | | Eff TC | 6.08 | 5.591 | 4.744 | 6.399 | 5.7035 |
| | | | (W/m · K) | | | | | |
| | | | TR (mm2- | 23.2 | 22.5 | 23.6 | 20.6 | 22.491 |
| | | | K/W) | | | | | |
| | t = | 778 | BLT (mm) | 0.142 | 0.123 | 0.111 | 0.134 | |
| | | | Eff TC | 6.247 | 5.384 | 4.854 | 6.511 | 5.749 |
| | | | (W/m · K) | | | | | |
| | | | TR (mm2- | 22.7 | 22.8 | 22.9 | 20.6 | 22.25617 |
| | | | K/W) | | | | | |
| | t = | 1000 | BLT (mm) | 0.14 | 0.122 | 0.108 | 0.13 | |
| | | | Eff TC | 6.058 | 5.538 | 4.814 | 6.247 | 5.66425 |
| | | | (W/m · K) | | | | | |
| | | | TR (mm2- | 23.1 | 22.0 | 22.4 | 20.8 | 22.09603 |
| | | | K/W) | | | | | |

TABLE 7A-C—after 4×10 min at 65° C. (done by hand) to mimic as made, but jostled around—the heat increase/decrease would cause movement due to heat expansion of parts.

| | | | |
|---|---|---|---|
| 1 | 2 | 3 | 4 |

TABLE 7A

| | | | | | | | |
|---|---|---|---|---|---|---|---|
| 85° C./85% RH | t = 0 | 0 | BLT (mm) | 0.08 | 0.063 | 0.074 | 0.073 |
| | | | Eff TC | 3.308 | 3.334 | 3.391 | 3.289 |
| | | | (W/m · K) | | | | |
| | | | TR (mm2- | 24.2 | 18.9 | 21.8 | 22.2 |
| | | | K/W) | | | | |
| | t = 250 hrs | 250 | BLT (mm) | 0.079 | 0.059 | 0.078 | 0.058 |
| | | | Eff TC | 2.764 | 3.845 | 4.149 | 2.671 |
| | | | (W/m · K) | | | | |
| | | | TR (mm2- | 28.6 | 15.3 | 18.8 | 21.7 |
| | | | K/W) | | | | |
| | t = 540 hrs | 540 | BLT (mm) | 0.086 | 0.067 | 0.077 | 0.074 |
| | | | Eff TC | 2.527 | 4.334 | 4.409 | 3.753 |
| | | | (W/m · K) | | | | |
| | | | TR (mm2- | 34.0 | 15.5 | 17.5 | 19.7 |
| | | | K/W) | | | | |
| | t = 850 hrs | 850 | BLT (mm) | 0.075 | 0.062 | 0.067 | 0.065 |
| | | | Eff TC | 1.235 | 3.623 | 3.403 | 2.995 |
| | | | (W/m · K) | | | | |
| | | | TR (mm2- | 60.7 | 17.1 | 19.7 | 21.7 |
| | | | K/W) | | | | |
| | t = 1000 hrs | 1000 | BLT (mm) | 0.085 | 0.059 | 0.072 | 0.069 |
| | | | Eff TC | 0.941 | 3.283 | 3.614 | 2.754 |
| | | | (W/m · K) | | | | |
| | | | TR (mm2- | 90.3 | 18.0 | 19.9 | 25.1 |
| | | | K/W) | | | | |

TABLE 7B

| | | | | | | | |
|---|---|---|---|---|---|---|---|
| 150° C. | t = 0 | 0 | BLT (mm) | 0.059 | 0.052 | 0.091 | 0.096 |
| soak | | | Eff TC | 3.207 | 3.182 | 3.313 | 3.294 |
| | | | (W/m · K) | | | | |
| | | | TR (mm2- | 18.4 | 16.3 | 27.5 | 29.1 |
| | | | K/W) | | | | |
| | t = 250 hrs | 250 | BLT (mm) | 0.057 | 0.049 | 0.094 | 0.091 |
| | | | Eff TC | 3.914 | 3.465 | 4.348 | 4.071 |
| | | | (W/m · K) | | | | |
| | | | TR (mm2- | 14.6 | 14.1 | 21.6 | 22.4 |
| | | | K/W) | | | | |
| | t = 550 hrs | 550 | BLT (mm) | 0.052 | 0.046 | 0.082 | 0.09 |
| | | | Eff TC | 3.339 | 3.015 | 3.844 | 4.116 |
| | | | (W/m · K) | | | | |
| | | | TR (mm2- | 15.6 | 15.3 | 21.3 | 21.9 |
| | | | K/W) | | | | |
| | t = 850 hrs | 850 | BLT (mm) | 0.05 | 0.046 | 0.079 | 0.09 |
| | | | Eff TC | 2.988 | 2.886 | 3.563 | 4.002 |
| | | | (W/m · K) | | | | |
| | | | TR (mm2- | 16.7 | 15.9 | 22.2 | 22.5 |
| | | | K/W) | | | | |
| | t = 1000 hrs | 1000 | BLT (mm) | 0.056 | 0.043 | 0.085 | 0.086 |
| | | | Eff TC | 2.998 | 2.485 | 3.804 | 3.75 |
| | | | (W/m · K) | | | | |
| | | | TR (mm2- | 18.7 | 17.3 | 22.3 | 22.9 |
| | | | K/W) | | | | |

TABLE 7C

| | | | | | | | |
|---|---|---|---|---|---|---|---|
| thermal | t = 0 | 0 | BLT (mm) | 0.064 | 0.076 | 0.067 | 0.067 |
| Cycle | | | Eff TC | 4.018 | 4.832 | 4.684 | 4.315 |
| 0° C.-100° C. | | | (W/m · K) | | | | |
| | | | TR (mm2- | 15.9 | 15.7 | 14.3 | 15.5 |
| | | | K/W) | | | | |
| | t = 225 | 225 | BLT (mm) | 0.057 | 0.065 | 0.058 | 0.06 |
| | cycles | | Eff TC | 5.102 | 5.866 | 6.16 | 5.44 |
| | | | (W/m · K) | | | | |
| | | | TR (mm2- | 11.2 | 11.1 | 9.4 | 11.0 |
| | | | K/W) | | | | |
| | t= | 485 | BLT (mm) | 0.058 | 0.065 | 0.057 | 0.059 |
| | | | Eff TC | 5.746 | 6.292 | 6.107 | 5.893 |
| | | | (W/m · K) | | | | |
| | | | TR (mm2- | 10.1 | 10.3 | 9.3 | 10.0 |
| | | | K/W) | | | | |
| | t= | 778 | BLT (mm) | 0.057 | 0.065 | 0.056 | 0.059 |
| | | | Eff TC | 5.675 | 6.609 | 6.245 | 6.105 |
| | | | (W/m · K) | | | | |
| | | | TR (mm2- | 10.0 | 9.8 | 9.0 | 9.7 |
| | | | K/W) | | | | |
| | t= | 1000 | BLT (mm) | 0.054 | 0.062 | 0.055 | 0.056 |
| | | | Eff TC | 5.366 | 6.156 | 6.073 | 5.675 |
| | | | (W/m · K) | | | | |
| | | | TR (mm2- | 10.1 | 10.1 | 9.1 | 9.9 |
| | | | K/W) | | | | |

TABLE 8A-C—after 5 h at 85° C. to mimic packages that have been out for a while before use, such as shipping to customer, assembly, or burn-in test.

| | | | |
|---|---|---|---|
| 1 | 2 | 3 | 4 |

TABLE 8A

| | | | | | | | |
|---|---|---|---|---|---|---|---|
| 85° C./85% RH | t = 0 | 0 | BLT (mm) | 0.093 | 0.1 | 0.109 | 0.073 |
| hours | hours | | Eff TC | 3.933 | 3.613 | 3.951 | 3.793 |
| | | | (W/m · K) | | | | |
| | | | TR (mm2- | 23.6 | 27.7 | 27.6 | 19.2 |
| | | | K/W) | | | | |
| | t= | 268 | BLT (mm) | 0.093 | 0.098 | 0.104 | 0.074 |
| | | | Eff TC | 4.135 | 3.878 | 4.033 | 4.408 |
| | | | (W/m · K) | | | | |
| | | | TR (mm2- | 22.5 | 25.3 | 25.8 | 16.8 |
| | | | K/W) | | | | |
| | t= | 570 | BLT (mm) | 0.093 | 0.097 | 0.106 | 0.077 |
| | | | Eff TC | 2.803 | 4.2 | 4.51 | 5.176 |
| | | | (W/m · K) | | | | |
| | | | TR (mm2- | 33.2 | 23.1 | 23.5 | 14.9 |
| | | | K/W) | | | | |
| | t= | 800 | BLT (mm) | 0.09 | 0.094 | 0.1 | 0.075 |
| | | | Eff TC | 2.981 | 3.493 | 2.287 | 2.149 |
| | | | (W/m · K) | | | | |
| | | | TR (mm2- | 30.2 | 26.9 | 43.7 | 34.9 |
| | | | K/W) | | | | |
| | t= | 1000 | BLT (mm) | 0.087 | 0.093 | 0.102 | 0.079 |
| | | | Eff TC | 2.083 | 2.946 | 1.873 | 1.695 |
| | | | (W/m · K) | | | | |
| | | | TR (mm2- | 41.8 | 31.6 | 54.5 | 46.6 |
| | | | K/W) | | | | |

TABLE 8B

| | | | | | | | |
|---|---|---|---|---|---|---|---|
| 150° C. | t = 0 | 0 | BLT (mm) | 0.069 | 0.074 | 0.083 | 0.086 |
| soak | hours | | Eff TC | 3.978 | 3.624 | 3.974 | 3.565 |
| | | | (W/m · K) | | | | |
| | | | TR (mm2- | 17.3 | 20.4 | 20.9 | 24.1 |
| | | | K/W) | | | | |
| | | 263 | BLT (mm) | 0.066 | 0.074 | 0.082 | 0.083 |
| | | | Eff TC | 3.405 | 3.777 | 3.895 | 3.637 |
| | | | (W/m · K) | | | | |
| | | | TR (mm2- | 19.4 | 19.6 | 21.1 | 22.8 |
| | | | K/W) | | | | |
| | | 570 | BLT (mm) | 0.067 | 0.075 | 0.082 | 0.085 |
| | | | Eff TC | 3.453 | 3.897 | 3.978 | 3.675 |
| | | | (W/m · K) | | | | |
| | | | TR (mm2- | 19.4 | 19.2 | 20.6 | 23.1 |
| | | | K/W) | | | | |
| | | 800 | BLT (mm) | 0.064 | 0.07 | 0.077 | 0.082 |
| | | | Eff TC | 3.28 | 3.587 | 3.626 | 3.537 |
| | | | (W/m · K) | | | | |
| | | | TR (mm2- | 19.5 | 19.5 | 21.2 | 23.2 |
| | | | K/W) | | | | |
| | | 1000 | BLT (mm) | 0.067 | 0.072 | 0.081 | 0.084 |
| | | | Eff TC | 3.418 | 3.659 | 3.836 | 3.651 |
| | | | (W/m · K) | | | | |
| | | | TR (mm2- | 19.6 | 19.7 | 21.1 | 23.0 |
| | | | K/W) | | | | |

TABLE 8C

| | | | | | | | |
|---|---|---|---|---|---|---|---|
| thermal | t = 0 | 0 | BLT (mm) | 0.06 | 0.093 | 0.101 | 0.086 |
| Cycle | cycles, | | Eff TC | 3.561 | 6.649 | 3.337 | 3.415 |
| 0° C.-100° C. | 1 hr/cycle | | (W/m · K) | | | | |
| | | | TR (mm2- | 16.8 | 14.0 | 30.3 | 25.2 |
| | | | K/W) | | | | |
| | t= | 263 | BLT (mm) | 0.057 | 0.09 | 0.098 | 0.08 |
| | | | Eff TC | 4.318 | 3.695 | 3.249 | 3.135 |
| | | | (W/m · K) | | | | |
| | | | TR (mm2- | 13.2 | 24.4 | 30.2 | 25.5 |
| | | | K/W) | | | | |
| | t= | 570 | BLT (mm) | 0.057 | 0.09 | 0.098 | 0.08 |
| | | | Eff TC | 4.595 | 3.68 | 3.384 | 3.284 |
| | | | (W/m · K) | | | | |
| | | | TR (mm2- | 12.4 | 24.5 | 29.0 | 24.4 |
| | | | K/W) | | | | |
| | t= | 800 | BLT (mm) | 0.057 | 0.092 | 0.098 | 0.081 |
| | | | Eff TC | 4.735 | 3.888 | 3.475 | 3.461 |
| | | | (W/m · K) | | | | |
| | | | TR (mm2- | 12.0 | 23.7 | 28.2 | 23.4 |
| | | | K/W) | | | | |
| | t= | 1000 | BLT (mm) | 0.056 | 0.09 | 0.104 | 0.083 |
| | | | Eff TC | 4.119 | 3.65 | 3.67 | 3.527 |
| | | | (W/m · K) | | | | |
| | | | TR (mm2- | 13.6 | 24.7 | 28.3 | 23.5 |
| | | | K/W) | | | | |

The test results of Table 6A, 6B, 6C, 7A, 7B, and 7C, and 8A, 8B, and 8C are set forth in FIG. 4. As apparent from FIG. 4, good thermal conductivity, i.e. low resistivity values were obtained. All three conditions generally showed excellent reliability as compared to standard cured greases that show pump-out and separation long before reaching 1,000 cycles. Surprisingly, without a cured step Formulation B revealed unexpected improved properties with regard to thermal conductivity and thermal resistivity.

With respect to the data set forth in Tables 3-8, they utilize tests that mimic an end product. That is, they are not an actual test of the end product but rather a test that gives an indication of the thermal conductivity and thermal resistivity of the gelled thermally conductive grease compositions of the present invention. These mimic tests have been found to yield generally much lower thermal conductivity and thermal resistivity values than tests such as those set forth in Table 2. Mimic tests are often utilized in the art for the sake of convenience and ease of preparation as opposed to testing the actual end product. The various mimic tests in Tables 3-8 relate to three individual tests, i.e. test of the thermal conductivity and thermal resistivity at 85° C. and 85% relative humidity; a test at 150° C., i.e. a high temperature soak test; and a third test alternating between cycles of 0° C. to 100° C. All three tests range in time from 0 to 1,000 hours. Table 3 relates to composition of Formulation A tested as dispersed whereas Table 4 relates to Formulation A tested to represent moderate heat exposure in a package whereas Table 5 relates to Formulation A tested to represent a high power exposure package. Table 6 relates to tests of Formulation B tested as dispersed, Table 7 relates to Formulation B tested at 150° C. high temperature soak test, and Table 8 relates to Formulation B tested at 0° C. to 100° C. cycle test, all at times up to 1,000 hours.

While in accordance with the patent statutes the best mode and preferred embodiment have been set forth, the scope of the invention is not intended to be limited thereto, but only by the scope of the attached claims.

What is claimed is:

1. A method for producing a thermally conductive gelled grease comprising the steps of:
mixing a thermally conductive composition comprising a silicone, a thermally conductive filler, and a silicone crosslinking agent; and
allowing the mixture to form a gel without any cure step at a temperature below 100° C. and producing a thermally conductive grease.

2. The method of claim 1, wherein said silicone comprises an unsaturated terminated diorganopolysiloxane and a saturated terminated diorganopolysiloxane, wherein the mole percent of said unsaturated diorganopolysiloxane is from about 0.3 to about 0.6 mole percent and wherein the mole percent of said saturated diorganopolysiloxane is from about 0.4 to about 0.7 mole percent based upon the total moles of said unsaturated terminated diorganopolysiloxane and said saturated terminated diorganopolysiloxane.

3. The method of claim 2, wherein said unsaturated group of said unsaturated diorganopolysiloxane is an alkenyl group having from 2 to about 10 carbon atoms, a cycloalkenyl group, or an alkene substituent located on an aromatic group, wherein the number of said unsaturated groups in said polymer is from 2 to about 5; wherein said saturated group of said saturated diorganopolysiloxane is an alkyl group having from 1 to 10 carbon atoms, an aryl group, an alkyl substituted aryl group, or a halogenated alkyl group; and allowing said mixture to form a gel at a temperature of from about 15° C. to about 85° C.

4. The method of claim 3, wherein said silicone crosslinking agent is one or more of a H-functional oligosiloxane having from about 1 to about 5 repeat units, a polymeric polydialkylsiloxane having SiH groups, a silicone resin having SiH groups, or an electro-negative group terminated siloxane oligomer.

5. The method of claim 4, wherein said unsaturated terminated diorganopolysiloxane is derived from vinyltrimethoxysilane, vinyltriethoxysilane, vinyltri-n-propoxysilane, vinyltri-iso-propoxysilane, vinyltri-n-butoxysilane, vinyltri-sec-butoxysilane, vinyltri-tert-butoxysilane, or vinyltriphenoxysilane, or any combination thereof; wherein the amount of said unsaturated diorganopolysiloxane is from about 0.3 mole percent to about 0.45 mole percent and wherein the amount of said saturated diorganopolysiloxane is from about 0.55 mole percent to about 0.7 mole percent based upon the total number of moles of said unsaturated diorganopolysiloxane and said saturated diorganopolysiloxane; and wherein the amount of said silicone crosslinking agent is from about 0.2 to about 5.0 moles of per mole of said unsaturated diorganopolysiloxane.

6. The method of claim 5, wherein said saturated diorganopolysiloxane is one or more of a dimethylpolysiloxane, a diethylpolysiloxane, or a methyl-ethylpolysiloxane, and allowing said mixture to form a gel at a temperature of from about 20° C. to about 50° C.

7. The method of claim 5, including producing a mechanically and chemically structured grease.

8. The method of claim 1, wherein said thermally conductive gelled grease has a thermal conductivity of at least about 4 W/mK; and a thermal resistivity of about 16 or less.

9. The method of claim 5, wherein the thermal conductivity of said thermally conductive gelled grease is at least about 5 W/mK; and wherein the thermal resistivity of said thermally conductive gelled grease composition is about 10 or less.

10. The method of claim 1, wherein said gelled thermally conductive grease has a greater thermally conductivity than said grease cured at a temperature above 100° C.

21. A method of making an electronic device comprising:
providing a substrate;
positioning a heat producing article adjacent to the substrate;
filling a space therebetween with a thermally conductive grease; and
applying a temperature below 100° C. to said composition and forming a gelled grease without a curing step.

12. The method of claim 11, wherein said thermally conductive grease comprises an unsaturated terminated diorganopolysiloxane, a saturated terminated diorganopolysiloxane, a thermally conductive filler, and a silicone crosslinking agent, wherein the mole percent of said unsaturated diorganopolysiloxane is from about 0.3 to about 0.6 mole percent and wherein the mole percent of said saturated diorganopolysiloxane is from about 0.4 to about 0.7 mole percent based upon the total moles of said unsaturated terminated diorganopolysiloxane and said saturated terminated diorganopolysiloxane, wherein said unsaturated group of said unsaturated diorganopolysiloxane is an alkenyl group having from 2 to about 10 carbon atoms, a cycloalkenyl group, or an alkene substituent located on an aromatic group, wherein the number of said unsaturated groups in said polymer is from 2 to about 5; and wherein said saturated group of said saturated diorganopolysiloxane is an alkyl group having from 1 to 10 carbon atoms, an aryl group, an alkyl substituted aryl group, or a halogenated alkyl group.

13. The method of claim 12, wherein said silicone crosslinking agent is one or more of a H-functional oligosiloxane having from about 1 to about 5 repeat units, a polymeric polydialkylsiloxane having SiH groups, a silicone resin having SiH groups, or an electro-negative group terminated siloxane oligomer, wherein said unsaturated terminated diorganopolysiloxane is derived from vinyltrimethoxysilane, vinyltriethoxysilane, vinyltri-n-propoxysilane, vinyltri-iso-propoxysilane, vinyltri-n-butoxysilane, vinyltri-sec-butoxysilane, vinyltri-tert-butoxysilane, or vinyltriphenoxysilane, or any combination thereof; wherein the amount of said unsaturated diorganopolysiloxane is from about 0.3 mole percent to about 0.45 mole percent and wherein the amount of said saturated diorganopolysiloxane is from about 0.55 mole percent to about 0.7 mole percent based upon the total number of moles of said unsaturated diorganopolysiloxane and said saturated diorganopolysiloxane; and wherein the amount of said silicone crosslinking agent is from about 0.2 to about 5.0 moles of per mole of said unsaturated diorganopolysiloxane.

14. The method of claim 11, including forming said gel in a electronics package during a burn-in or a test step (normally at a temperature of about 15° C. to about 85° C.), wherein said saturated diorganopolysiloxane is one or more of a dimethylpolysiloxane, a diethylpolysiloxane, or a methyl-ethylpolysiloxane, wherein the thermal conductivity of said thermally conductive gelled grease is at least about 4 W/mK; and wherein the thermal resistivity of said gelled grease is about 16 or less.

15. The method of claim 11, including forming said thermally conductive grease having a gel value of from the crossover point of a G′ and G″ to about 70% of said G′.

16. The method of claim 14, wherein said thermally conductive grease has a greater thermal conductivity than said grease cured at a temperature above 100° C.

17. A thermal conductive composition, comprising:
a gelled grease having chemical and mechanical structure derived from an unsaturated terminated diorganopolysiloxane, a saturated terminated diorganopolysiloxane, a silicone crosslinking agent, and a thermally conductive filler, said gelled grease having a thermal conductivity of at least about 4 W/mK and a thermal resistivity of about 16 or less.

18. The composition of claim 17, wherein the mole percent of said unsaturated diorganopolysiloxane is from about 0.3 to about 0.6 mole percent and wherein the mole percent of said saturated diorganopolysiloxane is from about 0.4 to about 0.7 mole percent based upon the total moles of said unsaturated terminated diorganopolysiloxane and said saturated terminated diorganopolysiloxane, wherein said unsaturated group of said unsaturated diorganopolysiloxane is an alkenyl group having from 2 to about 10 carbon atoms, a cycloalkenyl group, or an alkene substituent located on an aromatic group, wherein the number of said unsaturated groups in said polymer is from 2 to about 5; wherein said saturated group of said saturated diorganopolysiloxane is an alkyl group having from 1 to 10 carbon atoms, an aryl group, an alkyl substituted aryl group, or a halogenated alkyl group; wherein said gelled grease composition has a gel content from G′ equal to G″ to wherein G″ is 80% or less of G′; wherein said gelled grease having a thermal conductivity of about 5 to about 10 W/mK and a thermal resistivity of about 6 or less.

19. The composition of claim 18, wherein said unsaturated terminated diorganopolysiloxaneis derived from vinyltrimethoxysilane, vinyltriethoxysilane, vinyltri-n-propoxysilane, vinyltri-iso-propoxysilane, vinyltri-n-butoxysilane, vinyltri-sec-butoxysilane, vinyltri-tert-butoxysilane, or vinyltriphenoxysilane, or any combination thereof; wherein the amount of said unsaturated diorganopolysiloxane is from about 0.3 mole percent to about 0.45 mole percent and wherein the amount of said saturated diorganopolysiloxane is from about 0.55 mole percent to about 0.7 mole percent based upon the total number of moles of said unsaturated diorganopolysiloxane and said saturated diorganopolysiloxane; and wherein the amount of said silicone crosslinking agent is from about 0.2 to about 5.0 moles of per mole of said unsaturated diorganopolysiloxane; wherein said silicone crosslinking agent is one or more of a H-functional oligosiloxane having from about 1 to about 5 repeat units, a polymeric polydialkylsiloxane having SiH groups, a silicone resin having SiH groups, or an electro-negative group terminated siloxane oligomer, and wherein said gelled grease having a thermal conductivity of about 6 to about 9 W/mK and a thermal resistivity of about 6 or less.

20. The composition of claim 19, wherein said gelled grease has a crosslink structure such that G′ is equal to G″ to where G″ is 70% or less of said G′.
